(19) United States
(12) Patent Application Publication
(10) Pub. No.: US 2007/0220390 A1
(43) Pub. Date: Sep. 20, 2007

(54) Method and system for verifying equivalence of two representations of a stimulus pattern for testing a design

(76) Inventors: Sarah L. Bird, Plano, TX (US); Sundeep Chadha, Austin, TX (US); Maureen T. Davis, Round Rock, TX (US); Kirk E. Morrow, Round Rock, TX (US); Tung N. Pham, Austin, TX (US)

Correspondence Address: IBM CORPORATION, 3605 HIGHWAY 52 NORTH, DEPT 917, ROCHESTER, MN, 55901-7829, US

(21) Appl. No.: 11/367,940

(22) Filed: Mar. 4, 2006

(51) Int. Cl. G01R 31/28; G06F 11/00

(52) U.S. Cl. 714/741

(57) ABSTRACT

A method for verifying the equivalence of two representations of a stimulus pattern for testing a design is disclosed. The method includes receiving a base pattern file representing the stimulus pattern in a first file format. A derivative pattern file in a second file format is generated from the base pattern file. The derivative pattern file is parsed to create a first testing file in a third file format, and the first testing file is simulated against the design in a first simulation. Whether the first testing file passed the first simulation against the design is determined, and in response to determining that the first testing file does not pass the first simulation against the design, the base pattern file is parsed to create a second testing file in the third file format. The second testing file is simulated in a second simulation. Whether the second testing file passed the second simulation is determined, and, in response to determining that the second testing file passed the second simulation, a likely non-equivalence of the derivative pattern file and the base pattern file is indicated. In response to determining that the second testing file did not pass the second simulation, a likely equivalence of the derivative pattern file and the base pattern file is indicated.

### BACKGROUND OF THE INVENTION

1. Field of the Invention

The present invention relates in general to verifying designs and in particular to reducing resource requirements during verification. Still more particularly, the present invention relates to a system, method and computer program product for verifying the equivalence of two representations of a stimulus pattern for testing a design.

2. Description of the Related Art

With the increasing penetration of microprocessor-based systems into every facet of human activity, demands have increased on the microprocessor development and production community to produce systems that are free from data corruption. Microprocessors have become involved in the performance of a vast array of critical functions, and the involvement of microprocessors in the important tasks of daily life has heightened the expectation of reliability of calculative results. Whether the impact of errors would be measured in human lives or in mere dollars and cents, consumers of microprocessors have lost tolerance for error-prone results. Consumers will not tolerate, by way of example, miscalculations on the floor of the stock exchange, in the medical devices that support human life, or in the computers that control their automobiles. All of these activities represent areas where the need for reliable microprocessor results has risen to a mission-critical concern.

In the course of designing and manufacturing a chip, there is an important phase of the process called Design For Test (DFT). DFT engineers create a sequence of stimuli that are applied to the chip pins to exercise possible faults (stuck-at, slow to rise, slow to fall, etc.) on the chip. The fault can then propagate to an observation point in the chip where it can be detected. A group of stimuli is generally known as a vector, and a collection of vectors is referred to as a pattern. The vectors are applied to a set of input pins on the chip, and once the Design Under Test (DUT) is stimulated, the DUT outputs a response on the output pins. The results are then compared to a list of expected values located in the pattern file.

A device called an Automated Test Equipment (ATE) or tester is used to execute the commands that the pattern file specifies on the chip when it is still in wafer or module form. The tester is designed to drive predetermined inputs into the chip, record the outputs, and compare them against a set of expected values. All of these stimuli and expected values are specified in the pattern file. The DFT team utilizes software specially designed to analyze and check for manufacturing faults generates the original patterns.

DFT software used to generate the patterns is commonly referred to as a testbench. In addition, patterns generated by the testbench tool are referred to as testbench design patterns (TBDpatt). Patterns run on the tester itself are referred to as ATE files. The TBDpatt patterns generated by the DFT team do not run on the tester in their native form, because the tester does not accept the testbench-generated TBDpatt format. Therefore, a translation process has to occur. The first step of this translation process is for the DFT team to deliver patterns to the tester team in TBDpatt format, which is the pattern format the testbench tool produces. Once the tester team has received the TBDpatt, the tester team manipulates the pattern into an ATE format, which is understood by the tester.

As the Testbench tool has the ability to do software simulation of TBDpatt format patterns, DFT team can, and does, check for the correctness of the TBDpatt format patterns before they are delivered to the Tester team. Because the tester team has to manipulate the TBDpatt-formatted patterns to generate ATE-formatted patterns before the team can run them on the tester, and because there is no software simulation supported for ATE-formatted patterns, the equivalence between the, supposedly correct, TBDpatt-formatted patterns and ATE-formatted patterns cannot be established under the prior art. Therefore, when an ATE pattern is failing on the tester, but the TBDpatt pattern is passing simulation or failing with a different fail signature, it is difficult to determine whether the fail is a real hardware fail, the model is an inaccurate representation of the hardware or the ATE pattern is just an improper translation of the TBDpatt pattern.

Under the prior art, if the ATE file fails on the tester, the only choices available are to regenerate the TBDpatt pattern and go through the whole process again or to attempt to alter the pattern by hand. If the pattern appears to have major flaws, it will be regenerated. Otherwise, engineers will try to alter the pattern. However, there is no tool to help analyze the reason for the fail which makes hand alteration difficult. Also, once the pattern is altered there is no way to determine that it is correct other than run the pattern on the tester. As a result expensive Tester time is wasted, and the Tester is utilized more as a pattern debug tool vs. a hardware tester. Also, if through the hand alteration method a passing pattern is found, then it is difficult to alter the TBDpatt to match the changes, which means it is quite possible that the same mistakes will be made next time. The absence of any means of establishing the equivalence between the TBDpatt format patterns and ATE format patterns becomes a big stumbling block for the entire process and costs resource, time and money, when there are failures on the hardware.

What is needed is a method, system and computer program product for verifying the equivalence of two representations of a stimulus pattern for testing a design.

### SUMMARY OF THE INVENTION

A method for verifying the equivalence of two representations of a stimulus pattern for testing a design is disclosed. The method includes receiving a base pattern file representing the stimulus pattern in a first file format. A derivative pattern file in a second file format is generated from the base pattern file. The derivative pattern file is parsed to create a first testing file in a third file format, and the first testing file is simulated against the design in a first simulation. Whether the first testing file passed the first simulation against the design is determined, and in response to determining that the first testing file does not pass the first simulation against the design, the base pattern file is parsed to create a second testing file in the third file format. The second testing file is simulated in a second simulation. Whether the second testing file passed the second simulation is determined, and, in response to determining that the second testing file passed the second simulation, a likely non-equivalence of the derivative pattern file and the base pattern file is indicated. In response to determining that the second testing file did not pass the second simulation, a likely equivalence of the derivative pattern file and the base pattern file is indicated.

### BRIEF DESCRIPTION OF THE DRAWINGS

The present invention is described in a preferred embodiment in the following description with reference to the drawings, in which like numbers represent the same or similar elements, as follows:

FIG. 1 illustrates a block diagram of a general-purpose data processing system with which the present invention of a method, system and computer program product for verifying the equivalence of two representations of a stimulus pattern for testing a design; and

FIG. 2 is a high-level logical flowchart of a process for verifying the equivalence of two representations of a stimulus pattern for testing a design.

### DETAILED DESCRIPTION OF A PREFERRED EMBODIMENT

The present invention provides a method, system and computer program product for verifying the equivalence of two representations of a stimulus pattern for testing a design. The present invention is a tool that has the capability to simulate the response of a hardware design to patterns in both ATE and TBDpatt pattern formats. Using the present invention, equivalence can be established between various pattern types. Therefore, the present invention can uncover inaccurate models and translation errors, allowing DFT team members and tester team members to concentrate on debugging real hardware failures on the tester. While the present invention is described with respect to ATE formatted files, additional pattern formats can be supported in the same manner.

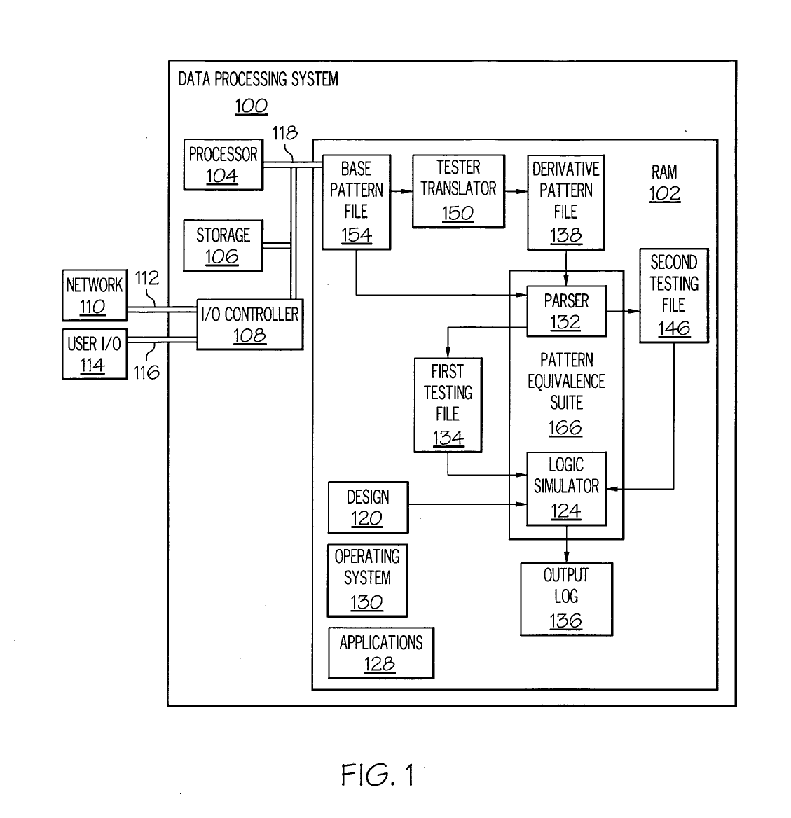

With reference now to the figures, and in particular with reference to FIG. 1, a block diagram of a general-purpose data processing system, in accordance with a preferred embodiment of the present invention, is depicted. Data processing system 100 contains a processing storage unit (e.g., RAM 102) and a processor 104. Data processing system 100 also includes non-volatile storage 106 such as a hard disk drive or other direct-access storage device. An Input/Output (I/O) controller 108 provides connectivity to a network 110 through a wired or wireless link, such as a network cable 112. I/O controller 108 also connects to user I/O devices 114 such as a keyboard, a display device, a mouse, or a printer through wired or wireless link 116, such as cables or a radio-frequency connection. System interconnect 118 connects processor 104, RAM 102, storage 106, and I/O controller 108.

Within RAM 102, data processing system 100 stores several items of data and instructions while operating in accordance with a preferred embodiment of the present invention, including a design 120 and output log 136 for interaction with a logic simulator 124. Other applications 128 and logic simulator 124 interface with processor 104, RAM 102, I/O control 108, and storage 106 through operating system 130. Other data structures in RAM 102 include a base pattern file 154 in the TBDpatt format, a tester-translator for converting base pattern file 154 to a derivative pattern file 138 in an ATE format, and a pattern equivalence suite 166. Pattern equivalence suite contains logic simulator 124 and a parser 132 for generating a first testing file 134 from derivative pattern file 138 and generating a second testing file 146 from base pattern file 154. One skilled in the data processing arts will quickly realize that additional components of data processing system 100 may be added to or substituted for those shown without departing from the scope of the present invention.

Design 120 represents the circuit structures under test in computer-aided design of digital circuits. Processor 104 executes instructions from programs, often stored in RAM 102, in the course of performing the present invention. In a preferred embodiment of the present invention, processor 104 executes logic simulator 124. Logic simulator 124 performs testing operations on design 120. Logic simulator 124 includes a computer program product, stored in RAM 102 and executed on processor 104, which provides a series of tools for activities such as equivalence checking, property checking, logic synthesis and false-paths analysis. Generally speaking, logic simulator 124 contains rule-based instructions for predicting the behavior of logically modeled items of hardware. Logic simulator 124 uses the series of rules contained in its own instructions, in conjunction with design 120, to represent the underlying logical problem structurally (as a circuit graph), and includes instructions for simulation on design 120 by applying inputs from first testing file 134 and second testing file 146 to design 120.

Pattern equivalence suite 166 performs two basic tasks. Parser 132 generates a first testing file 134 from derivative pattern file 138 and generates a second testing file 146 from base pattern file 154 by parsing the patterns in each file and outputting them in a common format. Logic simulator 124 then simulates the input of the pattern on the basis of first testing file 134 and second testing file 146. During parse, parser 132 breaks each task into smaller blocks of simple predefined stimuli or observations. Parser 132 and logic simulator 124 utilizes two languages to accomplish the tasks independently. Because the patterns from base pattern file 154 and derivative pattern file 138 are complex and do not follow the formatting rules very strictly, it is easier for parser 132 to use a language like Perl to parse the patterns efficiently. However, C++ code is used to drive the interface to logic simulator 124. Separating the tasks increases the efficiency of the present invention without introducing costly overhead, saving considerable about of simulation and run time.

For communication between the two tasks, parser 132 generates first testing file 134 and second testing file 146 in an intermediate file format called an SFD file (which stands for simulation for DFT). Perl code within parser 132 parses the original pattern within derivative pattern file 138 and base pattern file 154 and creates a SFD file (first testing file 134 or second testing file 146) to pass to the C++ code of logic simulator 124. Because the SFD-formatted first testing file 134 or second testing file 146 follows a rigid format, logic simulator 124 is able to easily use it. However, some of the DFT patterns within derivative pattern file 138 and base pattern file 154 are quite large, and it is undesirable to generate a comparably large first testing file 134 or second testing file 146. In some embodiments, a socket connection method for pattern simulation is used by logic simulator 124. As parser 132 parses the original pattern within derivative pattern file 138 and base pattern file 154, parser 132 feeds one line at a time from first testing file 134 or second testing file 146 to the C++ code of logic simulator 124 over a socket connection.

The C++ code of logic simulator 124 simulates each line of first testing file 134 or second testing file 146 as it receives the line. A tradeoff presented by the use of such a socket-connected embodiment is that errors occurring in the pattern format of derivative pattern file 138 and base pattern file 154 will not be found until they are encountered in the simulation by logic simulator 124, and in large patterns this discovery could occur hours or days after start. In an embodiment employing first testing file 134 or second testing file 146 as a single, large SFD file, all format errors are uncovered by logic simulator 124 in the first few minutes of simulation. Because each method has advantages and disadvantages for pattern simulation, the present invention supports both approaches so that user may choose the one that works best for any pattern type.

Parser 132 breaks the patterns of derivative pattern file 138 and base pattern file 154 into stim (stimuli), measure and pulse commands for the first testing file 134 or second testing file 146. Parser 132 creates instructions for logic simulator 124 to create data structures within output log 136 containing the names of pins to toggled and results measured in the event of a stim, pulse or measure command. Equivalent patterns within of derivative pattern file 138 and base pattern file 154 will have a nearly identical first testing file 134 and second testing file 146. The order of the creation of data structures may vary or a single stim may be broken into two or more back to back stims. However, first testing file 134 and second testing file 146 will elicit the same response from the logic simulator 124 in output log 136. A manual inspection of first testing file 134 or second testing file 146 will also reveal equivalence of the patterns. However, it is usually simpler to compare waveforms or simulation results from output log 136 to establish equivalence. The present invention can perform this comparison automatically and indicate the likely equivalence or non-equivalence of derivative pattern file 138 and base pattern file 154 and indicate this likely equivalence or non-equivalence directly within output log 136.

In the event that an ATE pattern (derivative pattern file 138) fails on the tester, the DFT team can use the present invention to simulate both the derivative pattern file 138 and base pattern file 154. If the results differ, then the present invention can indicate this likely non-equivalence directly within output log 136, pointing most likely to an error in the conversion process by testing translator 150 from base pattern file 154 to derivative pattern file 138 or in hand-modification of derivative pattern file 138. On the other hand, if the present invention indicates this likely equivalence, then it can be determined that there is no processing error. If both of first testing file 134 and second testing file 146 fail in simulation, the error is most likely in base pattern file 154, and a new base pattern file 154 will need to be generated. However if both of first testing file 134 and second testing file 146 pass in simulation, this most likely means that there is a real hardware fail within design 120 or that design 120 does not accurately reflect the actual hardware. Analysis of the simulation results from first testing file 134 and derivative pattern file 138 can help to determine the difference between these two types of fails.

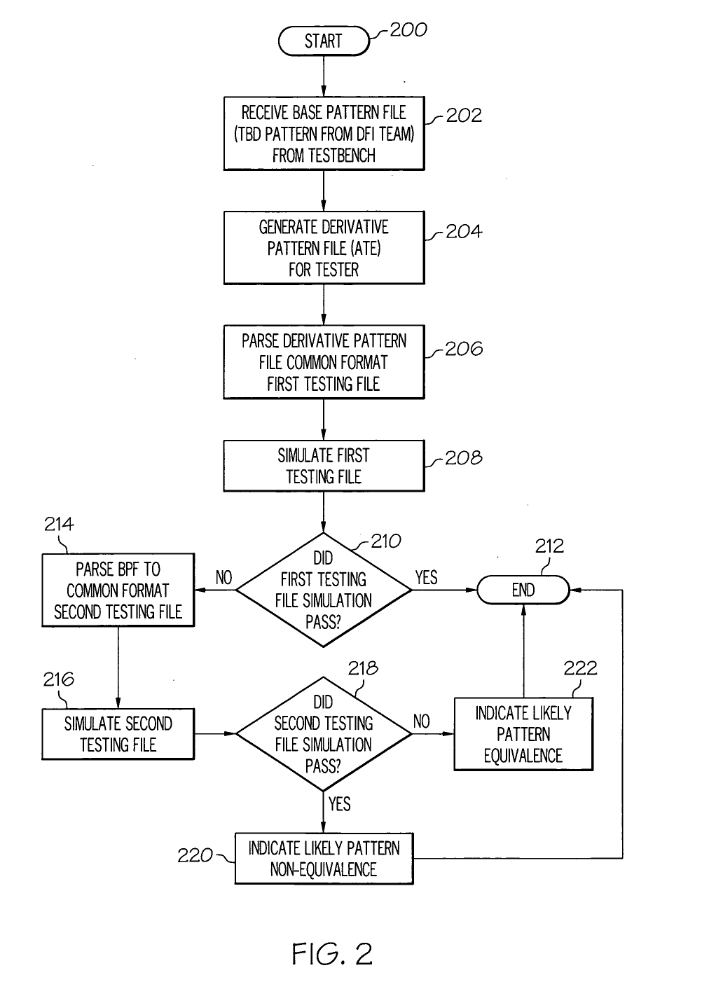

Turning now to FIG. 2, a high-level flowchart of a process for verifying the equivalence of two representations of a stimulus pattern for testing a design is disclosed. The process starts at step 200 and then moves to step 202, which illustrates pattern equivalence suite 166 receiving base pattern file 154. The process then proceeds to step 204, which depicts tester translator 150 translating base pattern file 154 to generate derivative pattern file 138. The process then moves to step 206, which illustrates parser 132 within equivalence suite 166 parsing derivative pattern file 138 to create first testing file 134. The process next proceeds to step 208.

Step 208 depicts logic simulator 124 simulating first testing file 134 against design 120. The process then moves to step 210, which illustrates pattern equivalence suite 166 determining whether first testing file 134 passed simulation against design 120 by logic simulator 124. If pattern equivalence suite 166 determines that first testing file 134 passed simulation against design 120 by logic simulator 124, then the process ends at step 212.

Returning to step 210, if pattern equivalence suite 166 determines that first testing file 134 did not pass simulation against design 120 by logic simulator 124, then the process next proceeds to step 214. Step 214 depicts parser 132 parsing base pattern file 154 to generate second testing file 146. The process then moves to step 218, which illustrates pattern equivalence suite 166 determining whether second testing file 146 passed simulation against design 120 by logic simulator 124. If pattern equivalence suite 166 determines that second testing file 146 passed simulation against design 120 by logic simulator 124, then the process next proceeds to step 220, which depicts pattern equivalence suite 166 indicating likely non-equivalence of base pattern file 154 and derivative pattern file 138 in output log 136. When pattern equivalence suite 166 indicates likely non-equivalence of base pattern file 154 and derivative pattern file 138 in output log 136, logic simulator 124 will insert simulator output into output log 136 to show non-equivalence. The process then ends at step 212.

Returning to step 218, if pattern equivalence suite 166 determines that second testing file 146 did not pass simulation against design 120 by logic simulator 124, then the process next proceeds to step 222, which depicts pattern equivalence suite 166 indicating likely equivalence of base pattern file 154 and derivative pattern file 138 in output log 136 The process then ends at step 212.

The present invention is a valuable tool to help establish equivalence between ATE and TBDpatt patterns. This equivalence check greatly reduces DFT debug time and helps to separate bad patterns, processing errors, and hardware and model failures. Ultimately, the tester can be used more frequently to test patterns and hardware and less often to debug patterns.

While the invention has been particularly shown as described with reference to a preferred embodiment, it will be understood by those skilled in the art that various changes in form and detail may be made therein without departing from the spirit and scope of the invention. It is also important to note that although the present invention has been described in the context of a fully functional computer system, those skilled in the art will appreciate that the mechanisms of the present invention are capable of being distributed as a program product in a variety of forms, and that the present invention applies equally regardless of the particular type of signal bearing media utilized to actually carry out the distribution. Examples of signal bearing media include, without limitation, recordable type media such as floppy disks or CD ROMs and transmission type media such as analog or digital communication links.

What is claimed is:

1. A method for verifying the equivalence of two representations of a stimulus pattern for testing a design, said method comprising:
receiving a base pattern file representing said stimulus pattern in a first file format;
parsing a derivative pattern file in a second file format to create a first testing file in a third file format;
simulating said first testing file against said design in a first simulation;
in response to determining that said first testing file does not pass said first simulation against said design, parsing said base pattern file to create a second testing file in said third file format;
simulating said second testing file in a second simulation against said design; and
in response to determining that said second testing file passed said second simulation, indicating a likely non-equivalence of said derivative pattern file and said base pattern file.

2. The method of claim 1, further comprising the step of generating from said base pattern file said derivative pattern file in said second file format.

3. The method of claim 1, further comprising the step of, in response to determining that said second testing file did not pass said second simulation, indicating a likely equivalence of said derivative pattern file and said base pattern file.

4. The method of claim 1, further comprising the step of determining whether said second testing file passed said second simulation against said design.

5. The method of claim 1, further comprising the step of determining whether said first testing file passed said first simulation against said design.

6. The method of claim 1, wherein said step of simulating said first testing file against said design in said first simulation further comprises simulating said first testing file against said design in said first simulation through communicating across a socket connection between a parser and a logic simulator while said step of parsing said derivative pattern file in said second file format to create said first testing file in said third file format is incomplete.

7. The method of claim 1, wherein said step of indicating said likely non-equivalence of said derivative pattern file and said base pattern file further comprises inserting one or more items of output from said logic simulator into an output log to show non-equivalence.

8. A system for verifying the equivalence of two representations of a stimulus pattern for testing a design, said system comprising:
means for receiving a base pattern file representing said stimulus pattern in a first file format;
means for parsing a derivative pattern file in a second file format to create a first testing file in a third file format;
means for simulating said first testing file against said design in a first simulation;
means for, in response to determining that said first testing file does not pass said first simulation against said design, parsing said base pattern file to create a second testing file in said third file format;
means for simulating said second testing file in a second simulation against said design; and
means for, in response to determining that said second testing file passed said second simulation, indicating a likely non-equivalence of said derivative pattern file and said base pattern file.

9. The system of claim 8, further comprising means for generating from said base pattern file said derivative pattern file in said second file format.

10. The system of claim 8, further comprising means for, in response to determining that said second testing file did not pass said second simulation, indicating a likely equivalence of said derivative pattern file and said base pattern file.

11. The system of claim 8, further comprising means for determining whether said second testing file passed said second simulation against said design.

12. The system of claim 8, further comprising means for determining whether said first testing file passed said first simulation against said design.

13. The system of claim 8, wherein said means for simulating said first testing file against said design in said first simulation further comprises means for simulating said first testing file against said design in said first simulation through communicating across a socket connection between a parser and a logic simulator while said step of parsing said derivative pattern file in said second file format to create said first testing file in said third file format is incomplete.

14. The system of claim 8, wherein said means for indicating said likely non-equivalence of said derivative pattern file and said base pattern file further comprises inserting one or more items of output from said logic simulator into an output log to show non-equivalence.

15. A machine-readable medium having a plurality of instructions processable by a machine embodied therein, wherein said plurality of instructions, when processed by said machine, causes said machine to perform a method comprising:
receiving a base pattern file representing said stimulus pattern in a first file format;
parsing a derivative pattern file in a second file format to create a first testing file in a third file format;
simulating said first testing file against said design in a first simulation;
in response to determining that said first testing file does not pass said first simulation against said design, parsing said base pattern file to create a second testing file in said third file format;
simulating said second testing file in a second simulation against said design; and
in response to determining that said second testing file passed said second simulation, indicating a likely non-equivalence of said derivative pattern file and said base pattern file.

16. The machine-readable medium of claim 15, said method further comprising the step of generating from said base pattern file said derivative pattern file in said second file format.

17. The machine-readable medium of claim 15, said method further comprising the step of, in response to determining that said second testing file did not pass said second simulation, indicating a likely equivalence of said derivative pattern file and said base pattern file.

18. The machine-readable medium of claim 15, said method further comprising the step of determining whether said second testing file passed said second simulation against said design.

19. The machine-readable medium of claim 15, said method further comprising the step of determining whether said first testing file passed said first simulation against said design.

20. The machine-readable medium of claim 15, wherein said step of simulating said first testing file against said design in said first simulation further comprises simulating said first testing file against said design in said first simulation through communicating across a socket connection between a parser and a logic simulator while said step of parsing said derivative pattern file in said second file format to create said first testing file in said third file format is incomplete.
